(19) United States
(12) Patent Application Publication
(10) Pub. No.: US 2022/0356580 A1
(43) Pub. Date: Nov. 10, 2022

(54) SUBSTRATE PROCESSING APPARATUS, METHOD OF MANUFACTURING SEMICONDUCTOR DEVICE AND NON-TRANSITORY COMPUTER-READABLE RECORDING MEDIUM

(71) Applicant: Kokusai Electric Corporation, Tokyo (JP)

(72) Inventors: Yusaku OKAJIMA, Toyama-shi (JP); Takatomo YAMAGUCHI, Toyama-shi (JP)

(73) Assignee: Kokusai Electric Corporation, Tokyo (JP)

(21) Appl. No.: 17/870,468

(22) Filed: Jul. 21, 2022

Related U.S. Application Data
(63) Continuation of application No. PCT/JP2020/008644, filed on Mar. 2, 2020.

(51) Int. Cl. C23C 16/455; H01L 21/67

(52) U.S. Cl. CPC C23C 16/45563; H01L 21/67248; H01L 21/67103

(57) ABSTRACT

According to one aspect of a technique the present disclosure, there is provided a substrate processing apparatus including: a substrate support configured to support a substrate; a reaction tube in which the substrate support is accommodated; a heater provided around the reaction tube; and an accommodation structure provided at a side surface of the reaction tube and configured to accommodate one or both of: a gas supply nozzle provided so as to extend from an outside of the reaction tube toward an inside of the reaction tube in a horizontal direction with respect to a surface of the substrate supported by the substrate support; and a first temperature measuring structure provided so as to extend from the outside of the reaction tube toward the inside of the reaction tube in the horizontal direction with respect to the surface of the substrate supported by the substrate support.

### CROSS-REFERENCE TO RELATED PATENT APPLICATION

This application is a bypass continuation application of PCT International Application No. PCT/JP2020/008644, filed on Mar. 2, 2020, in the WIPO, the entire contents of which are hereby incorporated by reference.

### BACKGROUND

### 1. Field

The present disclosure relates to a substrate processing apparatus, a method of manufacturing a semiconductor device and a non-transitory computer-readable recording medium.

### 2. Related Art

According to some related arts, there is provided a hot wall type heat treatment apparatus including: a process chamber in which a wafer is processed; a heater provided outside the process chamber and configured to heat the process chamber; a thermocouple capable of measuring a temperature of the process chamber; and a controller configured to be capable of performing a feedback control of the heater based on the temperature measured by the thermocouple.

However, according to the related arts described above, it may not be possible to accurately measure a temperature in the vicinity of the wafer (also referred to as a “substrate”). As a result, it may be difficult to improve a processing uniformity of the substrate.

### SUMMARY

According to the present disclosure, to address problems described above, there is provided a technique capable of improving a processing uniformity of a substrate.

To address the problems described above, according to one or more embodiments of the present disclosure, there is provided a technique related to a substrate processing apparatus including: a substrate support configured to support a substrate; a reaction tube in which the substrate support is accommodated; a heater provided around the reaction tube; and an accommodation structure provided at a side surface of the reaction tube and configured to accommodate one or both of: a gas supply nozzle provided so as to extend from an outside of the reaction tube toward an inside of the reaction tube in a horizontal direction with respect to a surface of the substrate supported by the substrate support; and a first temperature measuring structure provided so as to extend from the outside of the reaction tube toward the inside of the reaction tube in the horizontal direction with respect to the surface of the substrate supported by the substrate support.

### BRIEF DESCRIPTION OF THE DRAWINGS

FIG. 1 is a diagram schematically illustrating a cross-section of a part of a substrate processing apparatus according to a first embodiment of the present disclosure.

FIG. 2 is a diagram schematically illustrating a cross-section of a gas supply structure of the substrate processing apparatus according to the first embodiment of the present disclosure, taken along the line A-A, shown in FIG. 1.

FIG. 3 is a diagram schematically illustrating details of a portion B shown in FIG. 2 when the gas supply structure of the substrate processing apparatus according to the first embodiment of the present disclosure is inserted into an inner tube.

FIG. 4 is a diagram schematically illustrating details of the portion “B” shown in FIG. 2 when the gas supply structure of the substrate processing apparatus according to the first embodiment of the present disclosure is inserted into the inner tube and fixed by a nut.

FIG. 5 is a diagram schematically illustrating a cross-section of a part of the substrate processing apparatus according to the first embodiment of the present disclosure when a part of a plurality of gas supply structures is replaced with a temperature measuring structure.

FIG. 6 is a diagram schematically illustrating a cross-section of the temperature measuring structure of the substrate processing apparatus according to the first embodiment of the present disclosure.

FIG. 7 is an enlarged diagram schematically illustrating details of a portion “A” shown in FIG. 6 of the cross-section of the temperature measuring structure of the substrate processing apparatus according to the first embodiment of the present disclosure.

FIG. 8 is a graph schematically illustrating a relationship between a horizontal position and a temperature obtained by measuring with a plurality of temperature measuring structures installed in the substrate processing apparatus according to the first embodiment of the present disclosure.

FIG. 9 is a diagram schematically illustrating a temperature distribution in the horizontal direction and a vertical direction obtained from the relationship between the horizontal position and the temperature obtained by using the plurality of temperature measuring structures installed in the substrate processing apparatus according to the first embodiment of the present disclosure.

FIG. 10 is a block diagram schematically illustrating a configuration of a controller of the substrate processing apparatus according to the first embodiment of the present disclosure.

FIG. 11 is a flow chart schematically illustrating a process flow of a substrate processing method according to the first embodiment of the present disclosure.

FIG. 12 is a list schematically illustrating an example of items controlled by the controller of the substrate processing apparatus according to the first embodiment of the present disclosure.

FIG. 13 is a block diagram schematically illustrating details of a gas supply source of the substrate processing apparatus according to the first embodiment of the present disclosure.

FIG. 14 is a diagram schematically illustrating a cross-section of a part of a substrate processing apparatus according to a second embodiment of the present disclosure.

FIG. 15 is a diagram schematically illustrating a cross-section of a part of the substrate processing apparatus according to the first embodiment of the present disclosure when a part of the plurality of gas supply structures is replaced with a temperature measuring structure provided with a driving structure.

### DETAILED DESCRIPTION

The present disclosure relates to a technique capable of performing a uniform processing on each surface of a plurality of substrates to be processed simultaneously by measuring a temperature distribution inside a substrate processing apparatus in advance and by controlling conditions of a substrate processing using data of the temperature distribution measured in advance when the substrate processing is performed.

### Embodiments of Present Disclosure

Hereinafter, one or more embodiments (also simply referred to as “embodiments”) of the technique of the present disclosure will be described in detail with reference to the drawings. In the drawings for explaining the embodiments, like reference numerals represent like components, and redundant descriptions related thereto will be omitted in principle.

However, the technique of the present disclosure is not construed as being limited to the contents of the embodiments described below. Those skilled in the art will easily understand that specific configurations of the technique of the present disclosure can be changed without departing from the idea and the scope of the technique of the present disclosure.

### First Embodiment

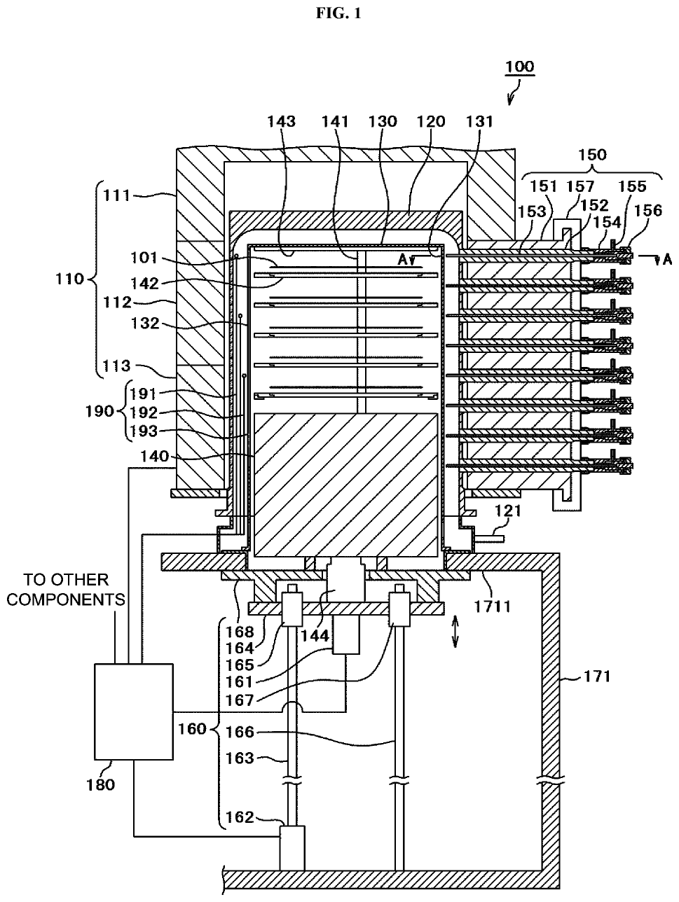

A first embodiment of the technique of the present disclosure will be described with reference to FIGS. 1 through 13.

Overall Configuration

FIG. 1 is a diagram schematically illustrating a cross-section of a part of a substrate processing apparatus 100 according to the first embodiment of the present disclosure. In FIG. 1, a reference numeral 110 indicates a heater, a reference numeral 120 indicates a reaction tube, a reference numeral 130 indicates an inner tube, a reference numeral 140 indicates a substrate support (which is a substrate retainer or a boat), a reference numeral 150 indicates a gas supply structure through which a gas such as a source gas and a reactive gas is supplied into the inner tube 130, a reference numeral 160 indicates a boat elevator capable of transferring (loading or unloading) the substrate support (boat) 140 into or out of the inner tube 130, and a reference numeral 180 indicates a controller capable of controlling operations of components constituting the substrate processing apparatus 100.

With the substrate support 140 (boat) provided in the inner tube 130 by operating the boat elevator 160, the heater 110 is capable of heating the inner tube 130 (and the reaction tube 120). For example, the heater 110 may be divided into a plurality of zone heaters (also referred to as “block heaters”) corresponding to blocks in a vertical direction (for example, a first zone heater 111, a second zone heater 112 and a third zone heater 113 shown in FIG. 1), and a heating state of the heater 110 can be controlled for each zone heater based on data of temperature sensors 191, 192 and 193 of a second temperature measuring structure 190 described later.

The substrate support (boat) 140 is configured to support (hold or accommodate) a plurality of substrates including a substrate (also referred to as a “wafer”) 101. Hereinafter, the plurality of substrates including the substrate 101 may also be simply referred to as substrates 101. More specifically, for example, a plurality of partition plates including a partition plate 142 supported by a partition plate support 141 are provided so as to space apart (or separate) the substrates 101 from one another. Hereinafter, the plurality of partition plates including the partition plate 142 may also be simply referred to as partition plates 142. A reference numeral 143 indicates a top plate provided at a top of the partition plates 142. A reference numeral 144 indicates a support column of the substrate support 140.

The substrate support 140 is connected to the boat elevator 160 by the support column 144, and the substrates 101 supported by the substrate support 140 may be transferred (loaded) into or transferred (unloaded) out of the inner tube 130 (that is, transferred to or from a portion below the inner tube 130) by the boat elevator 160.

The reference numeral 150 indicates the gas supply structure through which the gas such as the source gas and the reactive gas is supplied into the inner tube 130. A plurality of gas supply structures including the gas supply structure 150 are provided in the same plane as a cross-section shown in FIG. 1 such that the gas is supplied to each of the substrates 101 according to a vertical pitch (interval) of the substrates 101 supported by the substrate support 140. Hereinafter, the plurality of gas supply structures including the gas supply structure 150 may also be simply referred to as gas supply structures 150. The gas supply structures 150 are attached in a direction substantially parallel to surfaces of the substrates 101 supported by the substrate support 140 in the inner tube 130.

The inner tube 130 is provided with a plurality of gas introduction holes including a gas introduction hole 131 such that the gas supplied through the gas supply structures 150 can be introduced into the inner tube 130 at locations facing front ends of the gas supply structures 150. Hereinafter, the plurality of gas introduction holes including the gas introduction hole 131 may also be simply referred to as gas introduction holes 131.

In addition, a slit 132 is provided in a portion of a wall surface of the inner tube 130 facing the locations where the gas introduction holes 131 are provided. A part of the gas supplied into the inner tube 130 through the gas introduction holes 131, which did not contribute to a reaction inside the inner tube 130 such as the reaction on the surfaces of the substrates 101 supported by the substrate support 140, is discharged (or exhausted) from an inside of the inner tube 130 toward the reaction tube 120.

The gas discharged from the inside of the inner tube 130 toward the reaction tube 120 through the slit 132 is discharged to an outside of the reaction tube 120 by an exhaust structure (not shown) through an exhaust pipe 121.

As described above, the reference numeral 160 indicates the boat elevator. The boat elevator 160 is capable of transferring (loading or unloading) the substrate support 140 into or out of the inner tube 130. That is, the boat elevator 160 is capable of taking out the substrate support 140 from the inside of the inner tube 130 to an outside of the inner tube 130 (that is, to the portion below the inner tube 130), or conversely, the boat elevator 160 is capable of inserting the substrate support 140 from the outside of the inner tube 130 (that is, transferred from the portion below the inner tube 130) to the inside of the inner tube 130.

For example, the boat elevator 160 includes: a table 164 configured to support the support column 144 of the substrate support 140; an upper table 168 placed on the table 164; a rotational driving motor 161 fixed to the table 164 and rotationally driving the support column 144; a vertical driving motor 162 capable of driving the table 164 in the vertical direction; a ball screw 163 connected to the vertical driving motor 162; a ball nut 165 fixed to the table 164 and screwed with the ball screw 163; a guide shaft 166 configured to guide a vertical movement of the table 164; and a ball bearing 167 fixed to the table 164 and configured to receive the vertical movement along the guide shaft 166 of the table 164.

By driving the vertical driving motor 162 so as to elevate the upper table 168 by the boat elevator 160 until the upper table 168 abuts on an upper surface 1711 of a gantry frame 171, the substrates 101 supported by the substrate support 140 are arranged inside the inner tube 130 as shown in FIG. 1. In such a state, the upper table 168 comes into contact with the upper surface 1711 of the gantry frame 171 to maintain an airtight isolation of an inside of the reaction tube 120 from the outside of the reaction tube 120. Further, by vacuum-exhausting the inside of the reaction tube 120 through the exhaust pipe 121 by a vacuum exhaust structure (that is, the exhaust structure described above) such as a vacuum pump, it is possible to maintain the inside of the reaction tube 120 in a vacuum state.

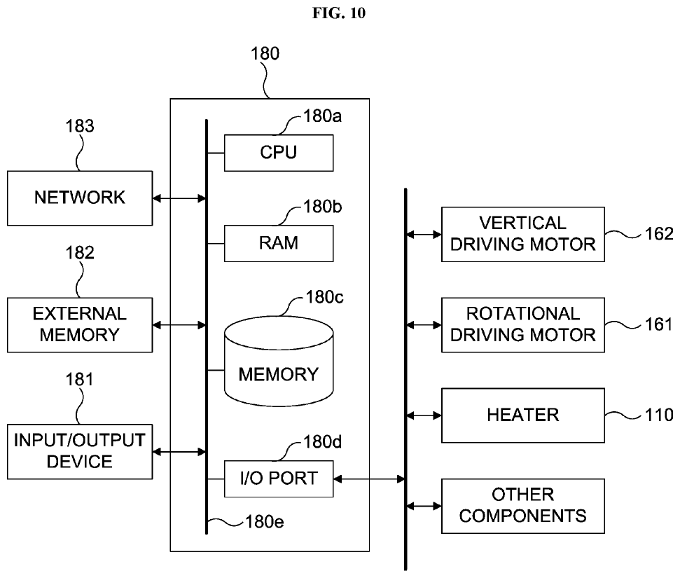

As described above, the reference numeral 180 indicates the controller capable of controlling the operations of the components constituting the substrate processing apparatus 100. The controller 180 will be described in detail with reference to FIG. 10.

As described above, the reference numeral 190 indicates the second temperature measuring structure capable of measuring a temperature of a side portion of an inner wall of the reaction tube 120. For example, as the second temperature measuring structure 190, the temperature sensors 191, 192 and 193 are provided at positions corresponding to the first zone heater 111, the second zone heater 112 and the third zone heater 113, respectively. Thereby, the second temperature measuring structure 190 is capable of measuring an inner temperature of the reaction tube 120 being heated by the heater 110. On the other hand, a first temperature measuring structure 210 will be described later.

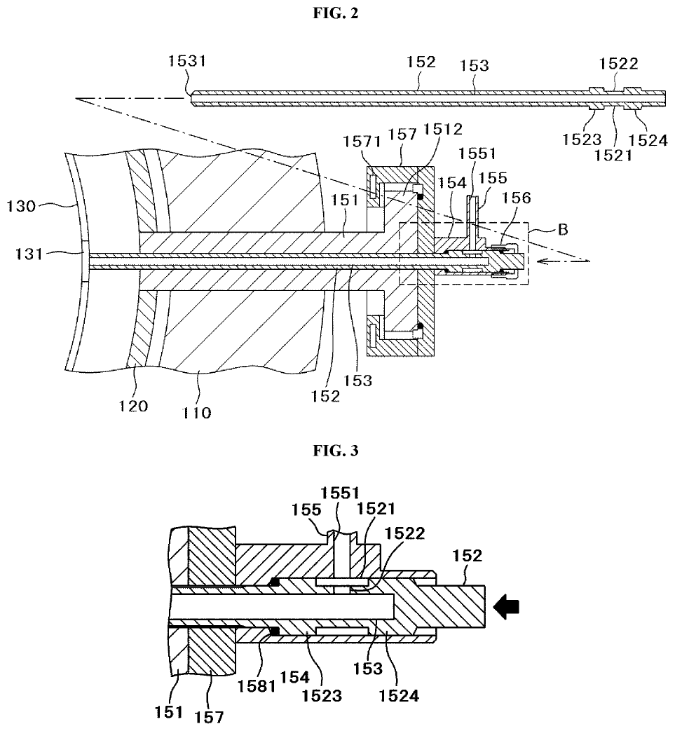

FIG. 2 is a diagram schematically illustrating a cross-section of the gas supply structure 150 taken along the line A-A shown in FIG. 1. FIGS. 3 and 4 are diagrams schematically illustrating details of a portion B surrounded by a dotted line shown in FIG. 2. As shown in FIG. 2, the gas supply structure 150 includes a configuration in which an introduction pipe 152 is inserted inside a main body structure 151. At the introduction pipe 152 mounted on the main body structure 151, a gas introduction structure 154 provided with a gas introduction pipe 155 through which the gas is supplied to the introduction pipe 152, a nut 156 and a bush 158 are provided. As shown in FIG. 1, a plurality of introduction pipes including the introduction pipe 152 are provided. Hereinafter, the plurality of introduction pipes including the introduction pipe 152 may also be simply referred to as introduction pipes 152. As shown in FIG. 1, a plurality of gas introduction pipes including the gas introduction pipe 155 are provided. Hereinafter, the plurality of gas introduction pipes including the gas introduction pipe 155 may also be simply referred to as gas introduction pipes 155.

The main body structure 151 passes through the heater 110 and extends to a surface where a front end (tip) of the main body structure 151 substantially coincides with an inner surface of the reaction tube 120. The main body structure 151 and the reaction tube 120 may be adhered to each other with an adhesive, or the main body structure 151 and the reaction tube 120 may be integrally formed as a single body.

A protrusion 1512 is provided on a location of the main body structure 151 opposite to the front end of the main body structure 151, and a protrusion cover 157 made of a metal is provided so as to cover a surface of the protrusion 1512. Further, a cooling water flow path 1571 through which cooling water for cooling the protrusion cover 157 flows may be provided on a location of the protrusion cover 157 facing the heater 110.

An opening 1531 is provided at a front end (tip) of the introduction pipe 152, and a hole 153 extending from the opening 1531 is provided inside the introduction pipe 152. Convex portions 1523 and 1524 are provided on a location of the introduction pipe 152 opposite to a portion where the opening 1531 is provided, and a hole 1522 leading to the hole 153 is provided at a concave portion 1521 between the convex portions 1523 and 1524.

The convex portions 1523 and 1524 of the introduction pipe 152 are fitted into holes provided at the gas introduction structure 154 such that the concave portion 1521 of the introduction pipe 152 faces a hole 1551 provided in the gas introduction pipe 155 of the gas introduction structure 154. The gas introduction pipe 155 is connected to a gas supply source shown in FIG. 13, and different types of gases can be supplied by being switched by a gas type switching structure (not shown).

On the other hand, with the introduction pipe 152 mounted on the gas introduction structure 154 and the main body structure 151, the introduction pipe 152 is set such that the opening 1531 at the front end of the introduction pipe 152 is located immediately before the gas introduction hole 131 provided in the inner tube 130.

FIG. 3 is a diagram schematically illustrating a state in which the introduction pipe 152 is inserted into the gas introduction structure 154, the protrusion cover 157 and the main body structure 151 along a direction of an arrow with an O-ring 1581 attached to a front end of the convex portion 1523. In such a state, the hole 1551 provided in the gas introduction pipe 155 of the gas introduction structure 154 is located at a location facing the concave portion 1521 of the introduction pipe 152, and communicates with the hole 153 of the introduction pipe 152 through the hole 1522 provided at the concave portion 1521.

FIG. 4 is a diagram schematically illustrating a state in which an O-ring 1592 is further attached between the convex portion 1524 and the bush 158 in addition to the state shown in FIG. 3, and the nut 156 is attached to a screw portion provided in the gas introduction structure 154 and tightened. By tightening the nut 156 to the screw portion provided in the gas introduction structure 154 and pressing the O-rings 1581 and 1592 against the bush 158, the O-rings 1581 and 1592 are deformed, and the airtightness between the introduction pipe 152 and the gas introduction structure 154 is ensured. As a result, by ensuring the airtightness from the gas introduction pipe 155 of the gas introduction structure 154 to the hole 153 of the introduction pipe 152, it is possible to prevent the gas supplied from the gas introduction pipe 155 to the introduction pipe 152 from flowing out.

By switching a gas type at the gas supply source shown in FIG. 13, the gas supply structure 150 is configured to receive a supply of the gas (that is, the source gas or the reactive gas) and a supply of the inert gas through the gas introduction pipe 155, to introduce the gas and the inert gas into the introduction pipe 152, and to supply the gas and the inert gas into the reaction tube 120 and the inner tube 130.

FIG. 13 is a block diagram schematically illustrating a configuration of the gas supply source. The gas supply source is configured such that a valve (or valves) and a MFC (or MFCs) are commonly used for each gas type, and nozzles 330-1, 330-2, 330-3, 330-4, 330-5, 330-6, 330-7 and 330-8 constituting a nozzle 330 are branched off such that each gas can be supplied into, for example, each of eight gas introduction pipes 155 provided in the gas supply structures 150 shown in FIG. 1.

That is, according to the present embodiment of the present disclosure, a flow rate of the source gas supplied through a gas supply pipe 331 is controlled by an MFC 321, and a start and a stop of the supply of the source gas are controlled by a valve 311. Then, the source gas is introduced to the nozzles 330-1 through 330-8, and is supplied into the gas introduction pipes 155 provided in the gas supply structures 150 through the nozzles 330-1 through 330-8.

In addition, a flow rate of the reactive gas supplied through a gas supply pipe 332 is controlled by an MFC 322, and a supply and a stop of the supply of the reactive gas are controlled by a valve 312. Then, the reactive gas is introduced to the nozzles 330-1 through 330-8, and is supplied into the gas introduction pipes 155 provided in the gas supply structures 150 through the nozzles 330-1 through 330-8.

In addition, a flow rate of the inert gas (carrier gas) supplied through a gas supply pipe 333 is controlled by an MFC 323, and a start and a stop of the supply of the inert gas are controlled by a valve 313. Then, the inert gas is introduced to the nozzles 330-1 through 330-8, and is supplied into the gas introduction pipes 155 provided in the gas supply structures 150 through the nozzles 330-1 through 330-8.

According to the present embodiment of the present disclosure, since the valve and the MFC are shared for each gas type, it is possible to simplify a configuration of a gas supply system such as the gas supply structures 150.

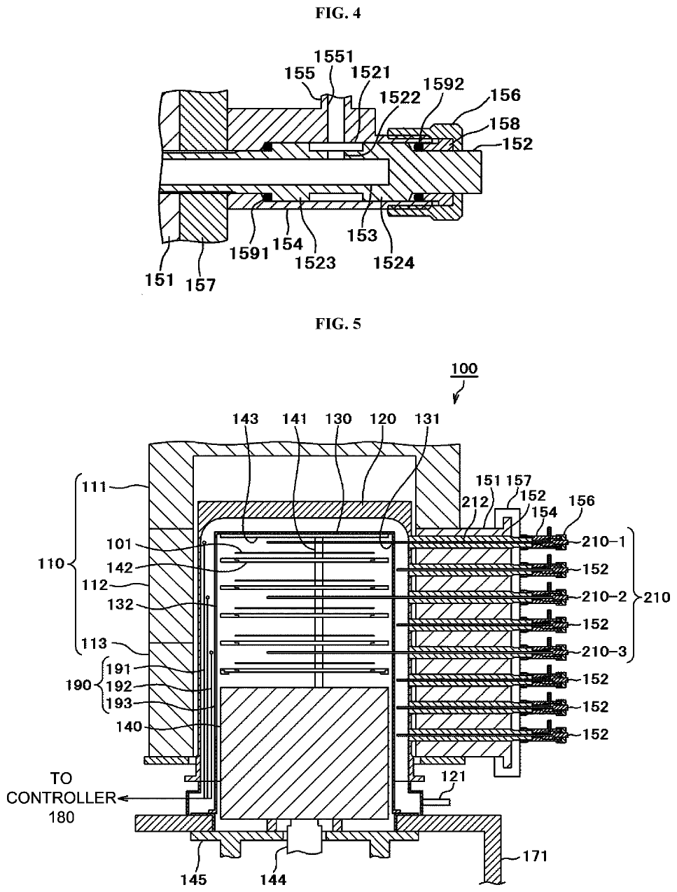

FIG. 5 is a diagram schematically illustrating a state in which a first introduction pipe, a third introduction pipe and a fifth introduction pipe among the introduction pipes 152 from the top are replaced with tubes 210-1, 210-2 and 210-3 in addition to the configuration of the gas supply structure 150 described with reference to FIG. 1. The tubes 210-1 through 210-3 are provided with temperature sensors (not shown) therein, respectively, and serve as the first temperature measuring structure 210 capable of measuring the inner temperature of the reaction tube 120. A length of a front end of each of the tubes 210-1 through 210-3 is set sufficiently that the front end of each of the tubes 210-1 through 210-3 reaches the inside of the inner tube 130 through the gas introduction hole 131 provided at the inner tube 130.

A temperature of a region heated by the first zone heater 111 of the heater 110 is measured by the tube 210-1, a temperature of a region heated by the second zone heater 112 of the heater 110 is measured by the tube 210-2, and a temperature of a region heated by the third zone heater 113 of the heater 110 is measured by the tube 210-3.

According to the present embodiment, a measurement position in the vertical direction (height direction) of the temperature sensor 191 of the second temperature measuring structure 190 with respect to the inner tube 130 is set substantially the same as a height of the tube 210-1, a measurement position in the vertical direction (height direction) of the temperature sensor 192 of the second temperature measuring structure 190 with respect to the inner tube 130 is set substantially the same as a height of the tube 210-2, and a measurement position in the vertical direction (height direction) of the temperature sensor 193 of the second temperature measuring structure 190 with respect to the inner tube 130 is set substantially the same as a height of the tube 210-3.

In addition, the front ends of the tubes 210-1 through 210-3 may be arranged at positions facing edges (ends) of the substrates 101. By arranging the front ends of the tubes 210-1 through 210-3 at the positions facing the edges of the substrates 101, it is possible to measure a temperature distribution on the substrates 101.

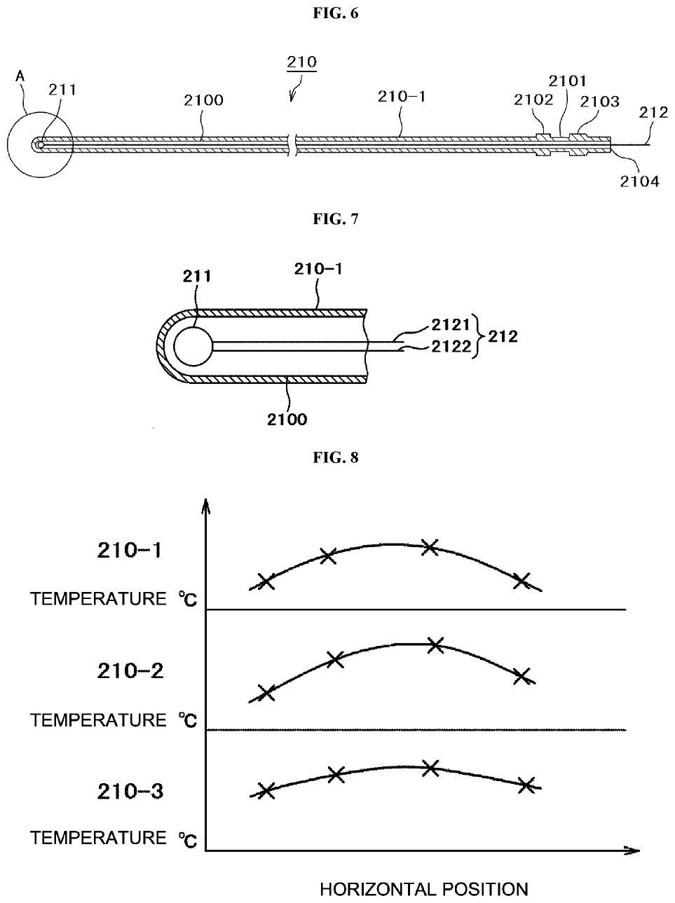

FIG. 6 is a diagram schematically illustrating a cross-section of the first temperature measuring structure 210 in which a plurality of temperature sensors including a temperature sensor 211 are installed inside the tubes 210-1 through 210-3. Hereinafter, the plurality of temperature sensors including the temperature sensor 211 may also be simply referred to as temperature sensors 211. Similar to the introduction pipe 152, each of the tubes 210-1 through 210-3 is provided with convex portions 2102 and 2103, and a concave portion 2101 is provided between the convex portions 2102 and 2103. However, since the gas is not introduced into the tubes 210-1 through 210-3, the concave portion 2101 may be omitted. However, in order to reduce the weight of the tubes 210-1 through 210-3, it is preferable to provide the concave portion 2101.

FIG. 7 is a diagram schematically illustrating details of a portion surrounded by a circle “A” shown in FIG. 6 at the front end of the tube 210-1 of the first temperature measuring structure 210. A hole 2100 is provided inside the tube 210-1. However, the hole 2100 is closed at the front end of the tube 210-1. Thus, unlike the introduction pipe 152, an opening is not provided at the front end of the tube 210-1. On the other hand, as shown in FIG. 6, the hole 2100 is provided to extend to a rear end of the tube 210-1 opposite to the front end of the tube 210-1 such that an opening 2104 is provided.

The temperature sensor (for example, a thermocouple type temperature sensor in the present embodiment) 211 is inserted into the hole 2100 provided in the tube 210-1 through the opening 2104, and is fixed near a front end portion of the hole 2100 provided in the tube 210-1. Electric wires 2121 and 2122 are provided to extend from the temperature sensor 211 to an outside of the opening 2104. Hereinafter, the electric wires 2121 and 2122 may be collectively referred to as electric wires 212.

In FIGS. 6 and 7, an example in which the temperature sensor 211 is installed inside the hole 2100 provided in the tube 210-1 is illustrated. However, according to the present embodiment, the temperature sensors 211 are fixed at a plurality of locations (for example, four locations) inside the hole 2100 with a predetermined interval therebetween. Thereby, it is possible to simultaneously measure temperatures inside the inner tube 130 at a plurality of positions at the same height.

In addition, while the present embodiment is described by way of an example in which the temperature sensors 211 are fixed at the plurality of locations inside the hole 2100 provided in the tube 210-1 with the predetermined interval therebetween, the temperature sensor 211 alone may be inserted inside the hole 2100 provided in the tube 210-1 without being fixed so that the temperature sensor 211 may be moved by a predetermined pitch inside the hole 2100 to measure the temperatures at the plurality of locations.

FIG. 8 is a graph schematically illustrating a distribution of the temperatures measured by each temperature sensor 211 installed inside the three tubes 210-1 through 210-3 shown in FIG. 5. The graph of FIG. 8 illustrates results of measuring the temperatures inside the inner tube 130 by installing the temperature sensors (for example, four temperature sensors) 211 inside each of the tubes 210-1 through 210-3.

A temperature measuring operation by each temperature sensor 211 of the first temperature measuring structure 210 is performed simultaneously with a temperature measuring operation by each of the temperature sensors 191, 192 and 193 of the second temperature measuring structure 190. As a result, it is possible to obtain a relationship between temperatures measured by the temperature sensors 191, 192 and 193 of the second temperature measuring structure 190 and temperatures measured by the four temperature sensors 211 installed inside each of the tubes 210-1 through 210-3 of the first temperature measuring structure 210.

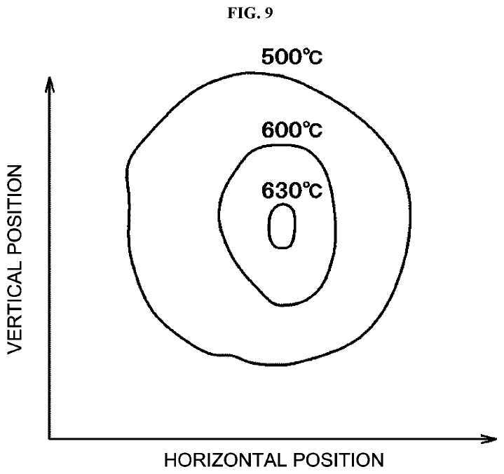

FIG. 9 is a graph schematically illustrating a temperature distribution in the horizontal direction and the vertical direction (height direction) in the inner tube 130 obtained from the graph of FIG. 8. By measuring the temperature at a plurality of positions in the horizontal direction and at a plurality of locations of different heights as described above, it is possible to obtain the temperature distribution in the vertical direction (height direction) inside the inner tube 130. As a result, it is possible to more accurately perform a temperature control operation inside the inner tube 130.

Controller

FIG. 10 is a block diagram schematically illustrating a configuration of the controller 180 of the substrate processing apparatus 100 according to the present embodiment. For example, the controller 180 is constituted by a computer including a CPU (Central Processing Unit) 180a, a RAM (Random Access Memory) 180b, a memory 180c and an input/output port (also simply referred to as an “I/O port”) 180d. The RAM 180b, the memory 180c and the I/O port 180d may exchange data with the CPU 180a through an internal bus 180e. For example, an input/output device 181 configured by a component such as a touch panel and an external memory 182 may be connected to the controller 180.

The memory 180c is configured by a memory medium such as a flash memory and a hard disk drive (HDD). For example, a control program configured to be capable of controlling the operations of the substrate processing apparatus 100, a process recipe containing information on sequences and conditions of a substrate processing described later, or a database may be readably stored in the memory 180c.

The process recipe is obtained by combining steps of the substrate processing described later such that the controller 180 can execute the steps to acquire a predetermined result, and functions as a program.

Hereafter, the process recipe and the control program may be collectively or individually referred to as a “program”. Thus, in the present specification, the term “program” may refer to the process recipe alone, may refer to the control program alone, or may refer to both of the process recipe and the control program. In addition, the RAM 180b functions as a memory area (work area) where a program or data read by the CPU 180a is temporarily stored.

The I/O port 180d is electrically connected to the components such as the heater 110, the rotational driving motor 161 and the vertical driving motor 162 of the boat elevator 160, a substrate loading/unloading port (not shown), a mass flow controller (not shown) and a vacuum pump (not shown).

In addition, in the present specification, “electrically connected” means that the components are connected by physical cables or the components are capable of communicating with one another to transmit and receive signals (electronic data) to and from one another directly or indirectly. For example, a device for relaying the signals or a device for converting or computing the signals may be provided between the components.

The CPU 180a is configured to read and execute the control program from the memory 180c and read the process recipe from the memory 180c in accordance with an instruction such as an operation command inputted from the controller 180. The CPU 180a is configured to be capable of controlling various operations in accordance with the contents of the process recipe such as an operation of supplying electrical power to the heater 110, a driving operation of the rotational driving motor 161 of the boat elevator 160, a driving operation of the vertical driving motor 162 of the boat elevator 160 and an opening and closing operation of the substrate loading/unloading port (not shown).

The controller 180 is not limited to a dedicated computer, and the controller 180 may be embodied by a general-purpose computer. For example, the controller 180 according to the present embodiment may be embodied by preparing the external memory 182 (e.g., a magnetic tape, a magnetic disk such as a flexible disk and a hard disk, an optical disk such as a CD and a DVD, a magneto-optical disk such as an MO, a semiconductor memory such as a USB memory and a memory card) in which the above-described program is stored, and installing the program onto the general-purpose computer using the external memory 182.

A method of providing the program to the computer is not limited to the external memory 182. For example, the program may be directly provided to the computer by a communication instrument such as a network 183 (Internet and a dedicated line) instead of the external memory 182. In addition, the memory 180c and the external memory 182 may be embodied by a non-transitory computer-readable recording medium. Hereinafter, the memory 180c and the external memory 182 may be collectively or individually referred to as a recording medium. Thus, in the present specification, the term “recording medium” may refer to the memory 180c alone, may refer to the external memory 182 alone, or may refer to both of the memory 180c and the external memory 182.

<Substrate Processing (Film-Forming Process)>

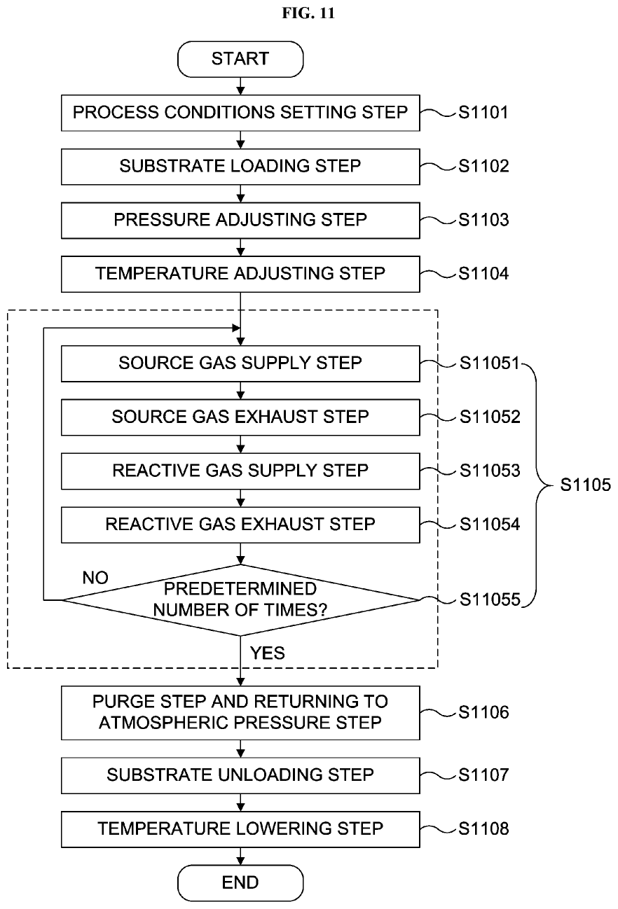

Hereinafter, the substrate processing (film-forming process) of forming a film on the substrate 101 using the substrate processing apparatus 100 described with reference to FIGS. 1 through 10 will be described with reference to FIG. 11.

Although the technique of the present disclosure can be applied to one or both of the film-forming process and an etching process, the substrate processing will be described based on a process of forming a silicon oxide (SiO₂) film on the substrate 101, which is an example of a process of forming the film on the substrate 101, as a part of a manufacturing process of a semiconductor device. The process of forming the film such as the SiO₂ film is performed in the reaction tube 120 of the substrate processing apparatus 100 described above. As described above, by executing the program stored in the memory 180c of the controller 180, the manufacturing process is performed.

In the substrate processing (the manufacturing process of the semiconductor device) according to the present embodiment, first, by driving the vertical driving motor 162 of the boat elevator 160 to elevate the substrate support (boat) 140, as shown in FIG. 1, the substrate support 140 is inserted into the inner tube 130 installed inside the reaction tube 120. In such a state, the substrate 101 placed on the substrate support 140 is provided above the partition plate 142 at a predetermined height (interval).

In such a state, the process of forming the SiO₂ film including:
(a) measuring the temperature of the side portion of the reaction tube 120 by the second temperature measuring structure 190 while heating the substrates 101 supported by the substrate support 140 inserted into the inner tube 130 by applying the electrical power to each of the zone heaters 111, 112 and 113 of the heater 110 of the heater 110, and operating the rotational driving motor 161 of the boat elevator 160 to rotate the substrate support 140 at a constant speed;
(b) a step of supplying Si₂Cl₆ (disilicon hexachloride) gas into the inner tube 130 with respect to the substrates 101 accommodated in the inner tube 130 through the introduction pipe 152 of the gas supply structure 150;
(c) a step of removing a residual gas in the reaction tube 120 by stopping an introduction of the Si₂Cl₆ (disilicon hexachloride) gas through the introduction pipe 152 and discharging the residual gas in the reaction tube 120 to the outside of the reaction tube 120 through the exhaust pipe 121;
(d) a step of supplying O₂ (oxygen) gas (or O₃ (ozone) gas or H₂O (water)) into the inner tube 130 with respect to the substrates 101 accommodated in the inner tube 130 through the introduction pipe 152; and
(e) a step of removing a residual gas in the reaction tube 120 by stopping an introduction of the O₂ (oxygen) gas (or the O₃ (ozone) gas or the H₂O (water)) through the introduction pipe 152 and discharging the residual gas in the reaction tube 120 to the outside of the reaction tube 120 through the exhaust pipe 121
is performed. The steps (b) to (e) described above are performed a plurality of times to form the SiO₂ film on the substrate 101.

Further, in the present specification, the term “substrate” may refer to “a substrate itself” or may refer to “a substrate and a stacked structure (aggregated structure) of predetermined layers or films formed on a surface of the substrate”. That is, the term “substrate” may collectively refer to the substrate and the layers or the films formed on the surface of the substrate. In addition, in the present specification, the term “a surface of a substrate” may refer to “a surface (exposed surface) of a substrate itself” or may refer to “a surface of a predetermined layer or a film formed on a substrate, i.e. a top surface (uppermost surface) of the substrate as a stacked structure”. In addition, in the present specification, the terms “substrate” and “wafer” may be used as substantially the same meaning.

Subsequently, a specific example of the film-forming process will be described with reference to a flow chart shown in FIG. 11.

Process Conditions Setting Step: S1101

First, the CPU 180a of the controller 180 reads the process recipe and the related database stored in the memory 180c and sets process conditions.

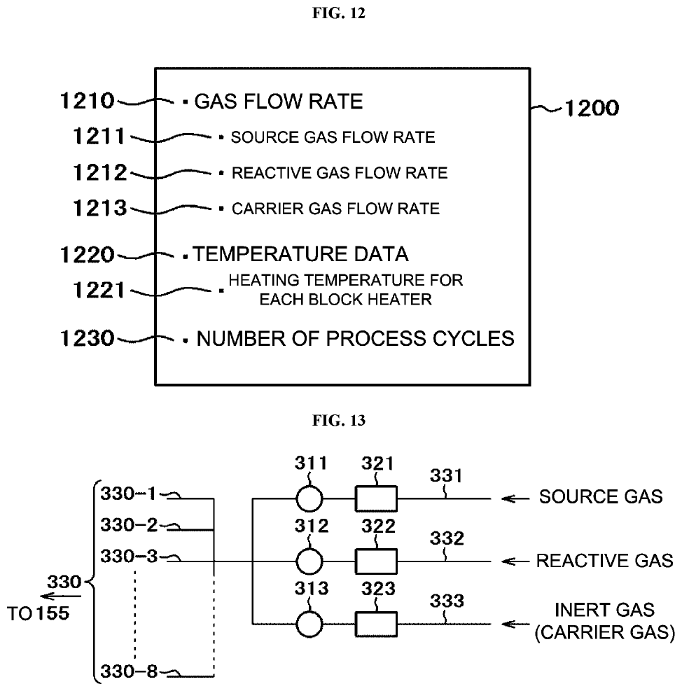

FIG. 12 is a list schematically illustrating an example of a process recipe 1200 read by the CPU 180a. The process recipe 1200 may include main items such as a “GAS FLOW RATE” 1210, a “TEMPERATURE DATA” 1220 and the “NUMBER OF PROCESS CYCLES” 1230.

Further, the “GAS FLOW RATE” 1210 may include items such as a “SOURCE GAS FLOW RATE” 1211, a “REACTIVE GAS FLOW RATE” 1212 and a “CARRIER GAS FLOW RATE” 1213, which indicate flow rates of the source gas, the reactive gas and the inert gas (carrier gas) supplied from the gas supply source (not shown) into the reaction tube 120 and the inner tube 130 through the introduction pipe 152 of the gas supply structure 150, respectively.

The “TEMPERATURE DATA” 1220 may include items such as a “HEATING TEMPERATURE FOR EACH BLOCK HEATER” 1221 which indicates a heating temperature for each of the zone heaters 111, 112 and 113 of the heater 110 (or the voltage applied for each of the zone heaters 111, 112 and 113). The heating temperature for each of the zone heaters 111, 112 and 113 may be obtained based on the relationship between the temperatures measured in advance by the temperature sensors 191, 192 and 193 of the second temperature measuring structure 190 and the temperatures measured by the four temperature sensors 211 installed inside each of the tubes 210-1 through 210-3 of the first temperature measuring structure 210.

Substrate Loading Step: S1102

With the substrates 101 placed on and supported by the substrate support 140 one by one, the substrate support 140 is elevated by operating the vertical driving motor 162 of the boat elevator 160 such that the substrate support 140 is transferred (loaded) into the inner tube 130 installed inside the reaction tube 120.

Pressure Adjusting Step: S1103

With the substrate support 140 loaded in the inner tube 130, an inner atmosphere of the reaction tube 120 is vacuum-exhausted by the vacuum pump (not shown) through the exhaust pipe 121 such that an inner pressure of the reaction tube 120 reaches and is maintained at a desired pressure.

Temperature Adjusting Step: S1104

In a state where the inner atmosphere of the reaction tube 120 is vacuum-exhausted by the vacuum pump (not shown), the heater 110 heats the reaction tube 120 based on the process recipe read in the step S1101 such that the inner temperature of the reaction tube 120 reaches and is maintained at a desired temperature. When heating the reaction tube 120, an amount of the electric current (or the applied voltage) supplied to each of the zone heaters 111, 112 and 113 of the heater 110 is feedback-controlled such that a desired temperature distribution of the inner temperature of the reaction tube 120 can be obtained. When feedback-controlling the amount of the electric current (or the applied voltage), by using temperature information measured by the temperature sensors 191, 192 and 193 of the second temperature measuring structure 190, a temperature distribution of a plurality of locations in the vicinity of the surface of the substrate 101 is estimated by the CPU 180a based on the relationship between temperature distribution data at the plurality of locations in the vicinity of the surface of the substrate 101 inside the inner tube 130 measured in advance by using the configuration as shown in FIG. 5 and the temperatures measured by the temperature sensors 191, 192 and 193 of the second temperature measuring structure 190 at this time. The heater 110 continuously heats the reaction tube 120 until at least a processing of the substrate 101 is completed.

In addition, a rotational speed of the substrate support 140 is adjusted by controlling the operation of the rotational driving motor 161 of the boat elevator 160 using the temperature information measured by the temperature sensors 191, 192 and 193 of the second temperature measuring structure 190.

That is, based on the relationship between the temperature distribution data at the plurality of locations in the vicinity of the surface of the substrate 101 inside the inner tube 130 measured in advance by using the configuration as shown in FIG. 5 and the temperatures measured by the temperature sensors 191, 192 and 193 of the second temperature measuring structure 190 at this time, temperatures of the plurality of locations in the vicinity of the surface of the substrate 101 is predicted by the CPU 180a by using the temperature distribution data (temperature information) measured by the temperature sensors 191, 192 and 193 of the second temperature measuring structure 190.

When the predicted temperatures are higher than a pre-set temperature, by controlling the operation of the rotational driving motor 161, the rotational speed of the substrate support 140 is increased above a pre-set rotational speed. On the other hand, when the predicted temperatures are lower than the pre-set temperature, by controlling the operation of the rotational driving motor 161, the rotational speed of the substrate support 140 is decreased below the pre-set rotational speed.

SiO₂ Film Forming Step: S1105

Subsequently, a step of forming the film such as the SiO₂ film serving as a first film (that is, an SiO₂ film forming step S1105) is performed. For example, a source gas supply step S11051, a source gas exhaust step S11052, a reactive gas supply step S11053, a reactive gas exhaust step S11054 and a determination step S11055 are performed as the SiO₂ film forming step S1105.

Source Gas Supply Step: S11051

By controlling the operation of the rotational driving motor 161, the rotational speed of the substrate support 140 supporting the substrates 101 is maintained at a pre-set speed. In such a state, the Si₂Cl₆ gas serving as the source gas whose flow rate is adjusted is supplied into the reaction tube 120 through the introduction pipe 152 of the gas supply structure 150. The source gas supplied to the reaction tube 120 is supplied into the inner tube 130 through the gas introduction hole 131 provided in the inner tube 130. A part of the source gas is not supplied into the inner tube 130 and stays in a space between the reaction tube 120 and the inner tube 130. A part of the source gas supplied through the introduction pipe 152 (which did not contribute to the reaction on the surface of the substrate 101) flows out to the reaction tube 120 through the slit 132 provided in the inner tube 130, and is exhausted through the exhaust pipe 121.

By introducing the Si₂Cl₆ gas into the inner tube 130 through the introduction pipe 152, the Si₂Cl₆ gas is supplied to the substrate 101 supported by the substrate support 140. For example, a flow rate of the Si₂Cl₆ gas supplied to the substrate 101 may be set within a range from 0.002 slm (standard liter per minute) to 1 slm, and more preferably, within a range from 0.1 slm to 1 slm.

When supplying the Si₂Cl₆ gas, as the carrier gas, the inert gas such as nitrogen (N₂) gas and argon (Ar) gas is supplied into the reaction tube 120 through the introduction pipe 152 together with the Si₂Cl₆ gas, and exhausted through the exhaust pipe 121. Specifically, a flow rate of the carrier gas may be set within a range from 0.01 slm to 5 slm, and more preferably, within a range from 0.5 slm to 5 slm.

The carrier gas such as the N₂ gas is supplied into the reaction tube 120 through the introduction pipe 152, and a part of the carrier gas is supplied into the inner tube 130 through the gas introduction hole 131 provided in the inner tube 130. On the other hand, most of the carrier gas such as the N₂ gas supplied into the reaction tube 120 is exhausted from the space between the reaction tube 120 and the inner tube 130 through the exhaust pipe 121. When the carrier gas is supplied and exhausted, a temperature of each of the zone heaters 111, 112 and 113 of the heater 110 is set such that a temperature of each of the substrates 101 (which are vertically arranged and supported by the substrate support 140) is within a range from, for example, 250° C. to 550° C. over an entire surface of each of the substrates 101.

In the source gas supply step S11051, the Si₂Cl₆ gas and the carrier gas such as the N₂ gas are supplied into the inner tube 130 without any other gas being supplied into the inner tube 130 together with the Si₂Cl₆ gas and the carrier gas. By supplying the Si₂Cl₆ gas into the inner tube 130, a silicon-containing layer whose thickness is, for example, within a range from less than a single atomic layer to several atomic layers is formed on the substrate 101 (that is, on a base film on the surface of the substrate 101).

Source Gas Exhaust Step: S11052

After the silicon-containing layer is formed on the surface of the substrate 101 heated to a predetermined temperature range by supplying the Si₂Cl₆ gas serving as the source gas into the inner tube 130 through the introduction pipe 152 for a predetermined time, a supply of the Si₂Cl₆ gas is stopped. In the source gas exhaust step S11052, the inner atmosphere of the reaction tube 120 is vacuum-exhausted by the vacuum pump (not shown) to remove the residual gas in the reaction tube 120 and the inner tube 130 such as the Si₂Cl₆ gas which did not react or which contributed to the formation of the silicon-containing layer out of the reaction tube 120 and the inner tube 130.

In the source gas exhaust step S11052, the N₂ gas serving as the carrier gas is continuously supplied into the reaction tube 120 through the introduction pipe 152. The N₂ gas serves as a purge gas, which improves the efficiency of removing the residual gas in the reaction tube 120 such as the Si₂Cl₆ gas which did not react or which contributed to the formation of the silicon-containing layer out of the reaction tube 120 and the inner tube 130.

Reactive Gas Supply Step: S11053

After the residual gas in the reaction tube 120 and the inner tube 130 is removed, the 02 gas serving as the reactive gas is supplied into the inner tube 130 through the introduction pipe 152. Then, a part of the O₂ gas which did not contribute to the reaction is exhausted out of the reaction tube 120 and the inner tube 130 through the exhaust pipe 121. Thereby, the O₂ gas is supplied to the substrate 101. Specifically, a flow rate of the O₂ gas supplied to the substrate 101 may be set within a range from 0.2 slm to 10 slm, and more preferably, within a range from 1 slm to 5 slm.

When supplying the O₂ gas, by stopping a supply of the N₂ gas through the introduction pipe 152, the supply of the N₂ gas into the reaction tube 120 and the inner tube 130 is stopped in order to prevent the N₂ gas from being supplied into the reaction tube 120 together with the O₂ gas. That is, the O₂ gas is supplied into the reaction tube 120 and the inner tube 130 without being diluted with the N₂ gas. As a result, it is possible to improve a film-forming rate of the SiO₂ film. In the reactive gas supply step S11053, the temperature of the heater 110 is set to substantially the same temperature as that of the source gas supply step S11051.

In the reactive gas supply step S11053, the O₂ gas is supplied into the reaction tube 120 and the inner tube 130 without any other gas being supplied into the reaction tube 120 and the inner tube 130 together with the O₂ gas. A substitution reaction occurs between the O₂ gas and at least a portion of the silicon-containing layer formed on the substrate 101 in the source gas (Si₂Cl₆ gas) supply step S11051. During the substitution reaction, silicon (Si) contained in the silicon-containing layer and oxygen (O) contained in the O₂ gas are bonded together. As a result, an SiO₂ layer containing silicon and oxygen is formed on the substrate 101.

Reactive Gas Exhaust Step: S11054

After the SiO₂ layer is formed, a supply of the O₂ gas into the reaction tube 120 and the inner tube 130 through the introduction pipe 152 is stopped. Then, the residual gas in the reaction tube 120 and the inner tube 130 such as the O₂ gas which did not react or which contributed to the formation of the SiO₂ layer and reaction by-products are removed out of the reaction tube 120 and the inner tube 130 in the same manners as in the source gas exhaust step S11052.

Determination Step (Performing a Predetermined Number of Times): S11055

By performing a cycle of the step S1105 in which the step S11051 through the step S11054 described above are sequentially performed in this order one or more times (that is, a predetermined number of times (n times)), the SiO₂ film of a predetermined thickness (for example, 0.1 nm to 2 nm) is formed on the substrate 101. It is preferable that the cycle described above is repeatedly performed a plurality of times, for example, preferably about 10 times to 80 times, and more preferably about 10 times to 15 times. Thereby, it is possible to form the film with a uniform thickness distribution on the surface of the substrate 101.

During performing the cycle described above (that is, from a start of the source gas supply step S11051 to an end of the reactive gas exhaust step S11054), by using the temperature information measured by the temperature sensors 191, 192 and 193 of the second temperature measuring structure 190, the temperatures of the plurality of locations in the vicinity of the surface of the substrate 101 is estimated by the CPU 180a based on the relationship between the temperature distribution data at the plurality of locations in the vicinity of the surface of the substrate 101 inside the inner tube 130 measured in advance by using the first temperature measuring structure 210 and the temperatures measured by the temperature sensors 191, 192 and 193 of the second temperature measuring structure 190 at this time. By using the estimated temperature data, the amount of the electric current (or the applied voltage) supplied to each of the zone heaters 111, 112 and 113 of the heater 110 is feedback-controlled such that the desired temperature distribution of the inner temperature of the reaction tube 120 can be obtained.

In addition, the rotational speed of the substrate support 140 is adjusted by controlling the operation of the rotational driving motor 161 of the boat elevator 160 by using the temperature information measured by the temperature sensors 191, 192 and 193 of the second temperature measuring structure 190.

After-Purge Step (Purge Step and Returning to Atmospheric Pressure Step): S1106

After repeatedly performing the step S11051 through the step S11055 of the step S1105 the predetermined number of times, the N₂ gas is supplied into the reaction tube 120 and the inner tube 130 through the introduction pipe 152, and is exhausted through the exhaust pipe 121. The N₂ gas serves as the purge gas, and inner atmospheres of the reaction tube 120 and the inner tube 130 are purged with the N₂ gas serving as the inert gas. Thereby, the residual gas in the reaction tube 120 and the inner tube 130 and the reaction by-products remaining in the reaction tube 120 and the inner tube 130 are removed out of the reaction tube 120. Then, the N₂ gas is filled in the reaction tube 120 until the inner pressure of the reaction tube 120 reaches an atmospheric pressure. Further, by stopping an application of the electrical power to each of the zone heaters 111, 112 and 113 of the heater 110, a heating by the heater 110 is stopped. The operation of the rotational driving motor 161 of the boat elevator 160 is stopped, and a rotation of the substrate support 140 is stopped.

Substrate Unloading Step: S1107

Thereafter, by operating the vertical driving motor 162 of the boat elevator 160, the substrate support (boat) 140 is lowered from the inner tube 130 of the reaction tube 120. Then, the substrate 101 with the film of a predetermined thickness formed on the surface thereof is transferred (discharged) out of the substrate support 140.

Temperature Lowering Step: S1108

Finally, the processing of the substrate 101 is completed by lowering the temperature of the heater 110 with the application of the electrical power to each of the zone heaters 111, 112 and 113 of the heater 110 stopped.

While the present embodiment is described by way of an example in which the SiO₂ film is formed on the substrate 101, the present embodiment is not limited thereto. For example, instead of the SiO₂ film, the present embodiment may also be applied when a silicon nitride film (Si₃N₄ film) or a titanium nitride film (TiN film) is formed. In addition, the present embodiment may also be applied to form another film other than the films described above. For example, the present embodiment may also be applied to form a film containing an element such as tungsten (W), tantalum (Ta), ruthenium (Ru), molybdenum (Mo), zirconium (Zr), hafnium (Hf), aluminum (Al), silicon (Si), germanium (Ge) and gallium (Ga), a film containing an element of the same family as the elements described above, a compound film of one or more elements described above and nitrogen (that is, a nitride film) or a compound film of one or more elements described above and oxygen (that is, an oxide film). Further, when forming the films described above, a halogen-containing gas or a gas containing at least one of a halogen element, an amino group, a cyclopentane group, oxygen (O), carbon (C) or an alkyl group may be used.

According to the present embodiment, it is possible to substantially uniformly maintain the temperatures of the substrates as desired over the entire surface of each of the substrates when the film is formed, and it is also possible to stably and uniformly perform the film-forming process on the surfaces of substrates (wafers) installed at a predetermined interval in the vertical direction inside the reaction tube.

In addition, according to the present embodiment of the present disclosure, it is possible to uniformly perform the film-forming process with respect to the substrates (wafers) arranged on the boat while feedback-controlling the heater based on temperature measurement results of the temperature sensors such as thermocouples configured to measure the inner temperature of the reaction tube (or a process chamber). It is also possible to provide a substrate processing apparatus capable of uniformly performing the film-forming process with respect to the surfaces of the substrates (wafers) installed at the predetermined interval in the vertical direction inside the reaction tube.

### Second Embodiment

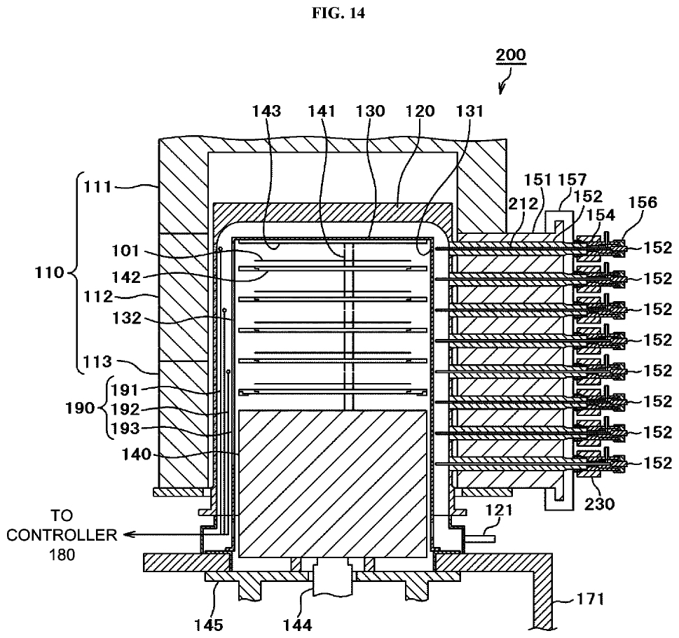

A second embodiment of the technique of the present disclosure will be described with reference to FIG. 14. As a substrate processing apparatus 200 according to the second embodiment, a configuration in which a heater 230 is attached to the protrusion cover 157 of the gas introduction structure 154 of the gas supply structure 150 of the substrate processing apparatus 100 according to the first embodiment shown in FIG. 1 may be used. The same reference numerals are assigned to the same components as in the first embodiment described with reference to FIG. 1, and redundant descriptions related thereto will be omitted.

When the inner temperature of the reaction tube 120 measured by the second temperature measuring structure 190 fixed inside the reaction tube 120 is lower than a pre-set temperature, according to the first embodiment, the electrical power is applied to each of the zone heaters 111, 112 and 113 constituting the heater 110 so as to heat the substrate 101 supported by the substrate support (boat) 140 inside the inner tube 130.

However, for example, the temperature of each of the zone heaters 111, 112 and 113 constituting the heater 110 deviates significantly from a predetermined temperature for some reason. In such a case, even when the electrical power applied to each of the zone heaters 111, 112 and 113 is increased, the temperature of each of the zone heaters 111, 112 and 113 may not immediately follow.

On the other hand, according to the present embodiment, the heater 230 is installed to the protrusion cover 157 of the gas introduction structure 154, and the heater 230 heats the gas inside the hole 153 provided in the introduction pipe 152 before the gas is supplied into the reaction tube 120.

That is, when the inner temperature of the reaction tube 120 corresponding to the positions of each of the zone heaters 111, 112 and 113 constituting the heater 110 and measured by the second temperature measuring structure 190 fixed inside the reaction tube 120 is lower than the pre-set temperature, the electrical power is applied to each of the zone heaters 111, 112 and 113 constituting the heater 110 so as to heat the substrate 101 supported by the substrate support (boat) 140 inside the inner tube 130. Further, the electrical power is applied to the heater 230 installed to the protrusion cover 157 of the gas introduction structure 154 so as to heat the gas introduction structure 154 and the introduction pipe 152 inserted into the gas introduction structure 154. Thereby, it is possible to heat the gas supplied into the reaction tube 120 through the hole 153 of the introduction pipe 152.

With such a configuration, it is possible to quickly respond to fluctuations in the inner temperature of the reaction tube 120 measured by the second temperature measuring structure 190, and it is also possible to constantly maintain a quality of the film formed on the substrate 101.

In addition, by installing the heater 230 at the protrusion cover 157 of the gas introduction structure 154, it is possible to preheat the gas supplied into the reaction tube 120, and it is also possible to reduce a temperature difference between a temperature of the gas immediately after being introduced into the inner tube 130 and a temperature of the gas staying inside the inner tube 130. Thereby, it is possible to more constantly maintain the quality of the film formed on the substrate 101.

According to the embodiments described above, when the film is being formed on the substrate, the temperature control operation can be performed for each of the zone heaters (block heaters) based on the data measured in advance. Thereby, when the film is being formed on the substrate, it is possible to maintain the temperature of the substrate substantially uniform, and it is also possible to form the film of a high quality on each surface of the substrates in a stable manner.

For example, the technique of the present disclosure may include the following examples.
(1) A substrate processing apparatus including:

a reaction tube in which a substrate is accommodated; and an accommodation structure provided at a side surface of the reaction tube so as to extend in a horizontal direction of the substrate,

wherein the accommodation structure is configured such that a gas supply nozzle provided so as to extend from an outside of the reaction tube toward an inside of the reaction tube in the horizontal direction of the substrate and a first temperature measuring structure provided so as to extend from the outside of the reaction tube toward the inside of the reaction tube in the horizontal direction of the substrate are capable of being inserted into the accommodation structure.
(2) The substrate processing apparatus further includes:

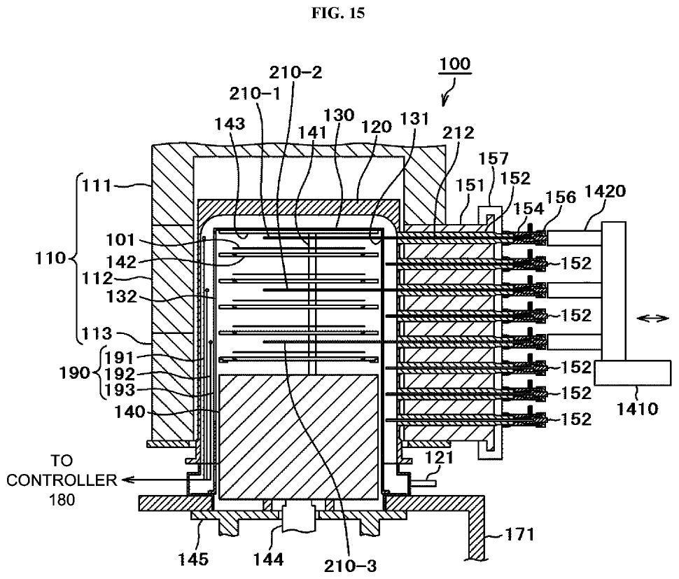

a slit for the accommodation structure; and a heater provided to surround the reaction tube.
(3) The heater is provided along an outer wall of the reaction tube.
(4) A plurality of substrates including the substrate are arranged in the reaction tube in a vertical direction, and a plurality of gas supply nozzles including the gas supply nozzle are arranged in a manner corresponding to the number of the plurality of substrates.
(5) Each of the plurality of gas supply nozzles is configured such that each of the plurality of gas supply nozzles is arranged between adjacent substrates among the plurality of substrates.
(6) The first temperature measuring structure is arranged for each of a plurality of zone heaters constituting the heater.
(7) The substrate processing apparatus further includes a controller configured to be capable of controlling the heater based on temperature data (a voltage value and a temperature value) output by the first temperature measuring structure.
(8) A plurality of zone heaters constituting the heater are provided in the vertical direction, and the substrate processing apparatus further includes a controller configured to be capable of controlling each of the plurality of zone heaters based on the temperature data output by the first temperature measuring structure.
(9) The substrate processing apparatus further includes a rotator configured to rotate a substrate support (boat) capable of supporting the substrate, and an inner temperature of the reaction tube is measured by the first temperature measuring structure while rotating the rotator.
(10) The accommodation structure is configured such that a second temperature measuring structure, which is arranged so as to extend in the horizontal direction of the substrate from the outside of the reaction tube, is capable of being inserted into the accommodation structure.
(11) The second temperature measuring structure is inserted at a position where the gas supply nozzle is inserted.
(12) The second temperature measuring structure is configured such that a front end (tip) of the second temperature measuring structure is capable of being inserted to an edge (end) of the substrate.
(13) The second temperature measuring structure includes a plurality of temperature measuring points in the horizontal direction with respect to a surface of the substrate.
(14) A plurality of second temperature measuring structures including the second temperature measuring structure are provided, and a temperature measuring operation is performed while pulling out at least one among the plurality of second temperature measuring structures.
(15) The substrate processing apparatus further includes an operating structure 1410 configured to operate the second temperature measuring structure in the horizontal direction. As shown in FIG. 15, the operating structure 1410 is configured to be movable in the horizontal direction with respect to the surface of the substrate. The second temperature measuring structure is fixed to a holding structure 1420 of the second temperature measuring structure connected to the operating structure 1410. The holding structure 1420 is configured to hold the electric wires 212 in the second temperature measuring structure such that at least the electric wires 212 are capable of being moved horizontally. That is, the temperature may be measured by moving the positions of the temperature sensors 211 while fixing the positions of the tubes 210-1 through 210-3. With such a configuration, it is possible to suppress changes in a gas flow due to the movement of the tubes 210-1 through 210-3.
(16) The temperature is measured while pulling out at least one among the plurality of second temperature measuring structures by the operating structure 1410.
(17) Temperature distribution data is generated based on results of measurement while pulling out at least one among the plurality of second temperature measuring structures.
(18) The heater is controlled based on the temperature distribution data.
(19) A rotation speed is controlled based on the temperature distribution data.
(20) A preheating temperature of a gas is controlled based on the temperature distribution data.
(21) The second temperature measuring structure includes a protective pipe and an inner pipe provided in the protective pipe. The second temperature measuring structure is configured such that the inner pipe alone is capable of being pulled out. The protective pipe is constituted by a pressure resistant structure. The temperature is capable of being measured in an environment close to an actual processing environment.

For example, the embodiments are described by way an example in which the plurality of accommodation structures are provided. However, the technique of the present disclosure is not limited thereto. For example, the technique of the present disclosure may also be applied when a single accommodation structure is provided.

For example, the embodiments are described by way an example in which the substrates are supported by the substrate support. However, the technique of the present disclosure is not limited thereto. For example, the technique of the present disclosure may also be applied when a single substrate is supported by the substrate support, or when the substrate support is configured to support the single substrate.

For example, the embodiments are described by way an example in which the film-forming process is performed as the part of the manufacturing process of the semiconductor device. However, the technique of the present disclosure is not limited thereto. For example, the technique of the present disclosure may also be applied when other processes such as a heat treatment process and a plasma treatment process are performed.

For example, the embodiments are described by way an example in which the substrate processing apparatus capable of performing the part of the manufacturing process of the semiconductor device is used. However, the technique of the present disclosure is not limited thereto. For example, the technique of the present disclosure may also be applied when other substrate processing apparatuses capable of processing a substrate such as a ceramic substrate, a substrate of a liquid crystal device and a substrate of a light emitting device are used.

According to the present disclosure, there is provided a technique capable of improving a processing uniformity of a substrate.

What is claimed is:

1. A substrate processing apparatus comprising:
a substrate support configured to support a substrate;
a reaction tube in which the substrate support is accommodated;
a heater provided around the reaction tube; and
an accommodation structure provided at a side surface of the reaction tube and configured to accommodate one or both of:
a gas supply nozzle provided so as to extend from an outside of the reaction tube toward an inside of the reaction tube in a horizontal direction with respect to a surface of the substrate supported by the substrate support; and
a first temperature measuring structure provided so as to extend from the outside of the reaction tube toward the inside of the reaction tube in the horizontal direction with respect to the surface of the substrate supported by the substrate support.

2. The substrate processing apparatus of claim 1, further comprising
one or more gas supply nozzles provided so as to extend from the outside of the reaction tube toward the inside of the reaction tube in the horizontal direction with respect to the surface of the substrate supported by the substrate support,
wherein the accommodation structure is further configured to accommodate the one or more gas supply nozzles.

3. The substrate processing apparatus of claim 2, wherein the substrate support is further configured to support one or more substrates,
each of the gas supply nozzle and the one or more gas supply nozzles is provided with an opening, and
the accommodation structure is further configured to accommodate the gas supply nozzle and the one or more gas supply nozzles such that a vertical position of the opening of at least one among the gas supply nozzle or the one or more gas supply nozzles is located between adjacent substrates among the substrate and the one or more substrates supported by the substrate support.

4. The substrate processing apparatus of claim 1, further comprising
a second temperature measuring structure fixed inside the reaction tube and configured to measure an inner temperature of the reaction tube,
wherein the first temperature measuring structure is detachably accommodated in the accommodation structure.

5. The substrate processing apparatus of claim 4, wherein the heater comprises a plurality of zone heaters, and the second temperature measuring structure comprises a plurality of temperature sensors respectively corresponding to heights of the plurality of zone heaters.

6. The substrate processing apparatus of claim 5, wherein the first temperature measuring structure is accommodated in the accommodation structure at a position corresponding to a height of each of the plurality of zone heaters.

7. The substrate processing apparatus of claim 1, wherein the heater comprises a plurality of zone heaters, and the first temperature measuring structure is accommodated in the accommodation structure at a position corresponding to a height of each of the plurality of zone heaters and comprises a plurality of temperature sensors at a plurality of positions respectively corresponding to heights of the plurality of zone heaters.

8. The substrate processing apparatus of claim 7, wherein the first temperature measuring structure is configured to simultaneously measure temperatures at the plurality of positions respectively corresponding to the heights of the plurality of zone heaters.

9. The substrate processing apparatus of claim 7, further comprising
a controller,
wherein the controller is configured to be capable of controlling the plurality of zone heaters of the heater based on temperature distribution data of a plurality of points at the plurality of positions respectively corresponding to the heights of the plurality of zone heaters measured by the first temperature measuring structure.

10. The substrate processing apparatus of claim 9, further comprising
a rotational driving structure configured to rotationally drive the substrate support,
wherein the controller is further configured to be capable of controlling the rotational driving structure based on the temperature distribution data of the plurality of points at the plurality of positions respectively corresponding to the heights of the plurality of zone heaters measured by the first temperature measuring structure so as to adjust a rotational speed of the substrate support.

11. The substrate processing apparatus of claim 9, further comprising
a gas supply nozzle heater configured to heat the gas supply nozzle,
wherein the controller is further configured to be capable of controlling the gas supply nozzle heater based on the temperature distribution data of the plurality of points at the plurality of positions respectively corresponding to the heights of the plurality of zone heaters measured by the first temperature measuring structure so as to control a heating temperature of a gas supplied into the reaction tube through the gas supply nozzle.

12. The substrate processing apparatus of claim 1, wherein a portion of the accommodation structure is configured to accommodate the gas supply nozzle or the first temperature measuring structure.

13. The substrate processing apparatus of claim 1, further comprising
an inner tube provided inside the reaction tube,
wherein the substrate support is accommodated in the inner tube,
the inner tube is provided with a hole facing an opening of the gas supply nozzle, and
a gas supplied into the reaction tube through the gas supply nozzle accommodated in the accommodation structure is introduced into the inner tube through the hole.

14. A substrate processing method comprising:
(a) accommodating a substrate support in a reaction tube;
(b) heating the reaction tube;
(c) measuring an inner temperature of the reaction tube by a first temperature measuring structure accommodated in an accommodation structure provided at a side surface of the reaction tube;
(d) accommodating the substrate support in the reaction tube with a substrate supported by the substrate support; and
(e) processing the substrate by heating the substrate based on a measurement result in (c).

15. The substrate processing method of claim 14, in (e), a heater configured to heat the reaction tube is controlled based on a relationship between a temperature measured by the first temperature measuring structure before (e) and a temperature measured by a second temperature measuring structure provided inside the reaction tube.

16. The substrate processing method of claim 14, wherein, in (e), when processing the substrate based on a relationship between a temperature measured by the first temperature measuring structure before (e) and a temperature measured by a second temperature measuring structure provided inside the reaction tube, and
based on temperature data inside the reaction tube measured by the second temperature measuring structure provided inside the reaction tube, a temperature in vicinity of an upper surface of the substrate in the reaction tube is estimated, and a rotation of the substrate support is controlled based on a result of the temperature estimated.

17. The substrate processing method of claim 14, wherein, in (e), when processing the substrate based on a relationship between a temperature measured by the first temperature measuring structure before (e) and a temperature measured by a second temperature measuring structure provided inside the reaction tube, and
based on temperature data inside the reaction tube measured by the second temperature measuring structure provided inside the reaction tube, a preheating temperature of a gas supplied into the reaction tube through the gas supply nozzle is controlled.

18. A non-transitory computer-readable recording medium storing a program that causes, by a computer, a substrate processing apparatus to perform:
(a) accommodating a substrate support in a reaction tube;
(b) heating the reaction tube;
(c) measuring an inner temperature of the reaction tube by a first temperature measuring structure accommodated in an accommodation structure provided at a side surface of the reaction tube;
(d) accommodating the substrate support in the reaction tube with a substrate supported by the substrate support; and
(e) processing the substrate by heating the substrate based on a measurement result in (c).

19. A method of manufacturing a semiconductor device comprising the substrate processing method of claim 14.
